(19) United States
(12) Patent Application Publication
(10) Pub. No.: US 2018/0120392 A1
(43) Pub. Date: May 3, 2018

(54) SUPERCONDUCTING MAGNET COOLING SYSTEM

(71) Applicant: General Electric Company, Schenectady, NY (US)

(72) Inventors: Evangelos Trifon Laskaris, Schenectady, NY (US); William E-Wei Chen, Florence, SC (US); Longzhi Jiang, Florence, SC (US); Tao Zhang, Niskayuna, NY (US); Haixia Xi, Florence, SC (US); Jun Li, Shanghai (CN)

(21) Appl. No.: 15/572,849

(22) PCT Filed: Apr. 28, 2016
(86) PCT No.: PCT/US16/29713

§ 371 Date: Nov. 9, 2017

(30) Foreign Application Priority Data
May 11, 2015 (CN) 201510236104.7

(51) Int. Cl. G01R 33/38; G01R 33/3815; H01F 6/04

(52) U.S. Cl. CPC G01R 33/3804; H02K 55/00; H01F 6/04; G01R 33/3815

(57) ABSTRACT

A superconducting magnet cooling system is disclosed. The superconducting magnet cooling system includes a superconducting magnet; a liquid cryogen vessel for cooling the superconducting magnet; a heat exchanger device in fluid communication with the liquid cryogen vessel; a cryorefrigerator for heat exchange with the heat exchanger device; and a flexible connection device having high thermal conductivity and thermally connecting the cryorefrigerator and the heat exchanger device to provide vibration isolation of the cryorefrigerator from the heat exchange device.

### CROSS-REFERENCE TO RELATED APPLICATIONS

This is a national stage application under 35 U.S.C. § 371 (c) of PCT Patent Application No. PCT/US2016/029713, filed on Apr. 28, 2016, which claims priority to Chinese Patent Application No. 201510236104.7, filed on May 11, 2015, the disclosures of which are incorporated herein by reference in their entireties.

### BACKGROUND

This disclosure relates generally to a magnetic resonance imaging (MRI) system, and more particularly to a superconducting magnet cooling system.

This disclosure relates generally to a magnetic resonance imaging (MRI) system, and more particularly to a superconducting magnet cooling system.

As is well known, a superconducting magnet can be made superconducting by placing it in an extremely cold environment, such as by enclosing it in a cryostat or pressure vessel containing liquid helium or other liquid cryogen. A cryorefrigerator is widely used to keep a cryogenic temperature. The extreme cold can ensure that the magnet coils are maintained in superconducting operation, such that when a power source is initially connected to the magnet coils (for a period, for example, of 10 minutes) to introduce a current flow through the coils, the current will continue to flow through the coils even after the power source is removed due to the absence of electrical resistance in the coils, thereby maintaining a strong magnetic field. Superconducting magnet cooling system finds wide application in the field of MRI.

However, when the cryorefrigerator is in operation, the cryorefrigerator may introduce mechanical vibrations which can also affect image quality of MRI. In a conventional superconducting magnet cooling system, a second stage of the cryorefrigerator is usually rigidly connected to a recondenser and bellow tubes are used to provide vibration isolation of the recondenser from the superconducting magnet. But the bellow tubes cannot endure high pressure, only low pressure cryogen can be used in cooling the superconducting magnet, so the conventional superconducting magnet cooling system limits the superconducting magnet cooling to low pressure cryogen.

### BRIEF DESCRIPTION

In one aspect of embodiments of the present invention, a superconducting magnet cooling system is provided. The superconducting magnet cooling system comprises a superconducting magnet; a liquid cryogen vessel for cooling the superconducting magnet; a heat exchanger device in fluid communication with the liquid cryogen vessel; a cryorefrigerator for heat exchange with the heat exchanger device; and a flexible connection device having high thermal conductivity and thermally connecting the cryorefrigerator and the heat exchanger device to provide vibration isolation of the cryorefrigerator from the heat exchange device.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic block diagram of a superconducting magnet cooling system in accordance with an embodiment of the present invention;

FIG. 2 is a perspective assembled view of a coldhead sleeve of a cryorefrigerator and a recondenser in accordance with an embodiment of the present invention;

FIG. 3 is a front view of the coldhead sleeve and the recondenser of FIG. 2; and

FIG. 4 is a perspective exploded view of the coldhead sleeve and the recondenser of FIG. 2.

### DETAILED DESCRIPTION

Embodiments of the present disclosure will be described hereinbelow with reference to the accompanying drawings. In the following description, well-known functions or constructions are not described in detail to avoid obscuring the disclosure in unnecessary detail.

Unless defined otherwise, technical and scientific terms used herein have the same meaning as is commonly understood by one of ordinary skill in the art to which this disclosure belongs. The terms “first”, “second”, and the like, as used herein do not denote any order, quantity, or importance, but rather are used to distinguish one element from another. Also, the terms “a” and “an” do not denote a limitation of quantity, but rather denote the presence of at least one of the referenced items. The term “or” is meant to be inclusive and mean either or all of the listed items. The use of “including,” “comprising” or “having” and variations thereof herein are meant to encompass the items listed thereafter and equivalents thereof as well as additional items.

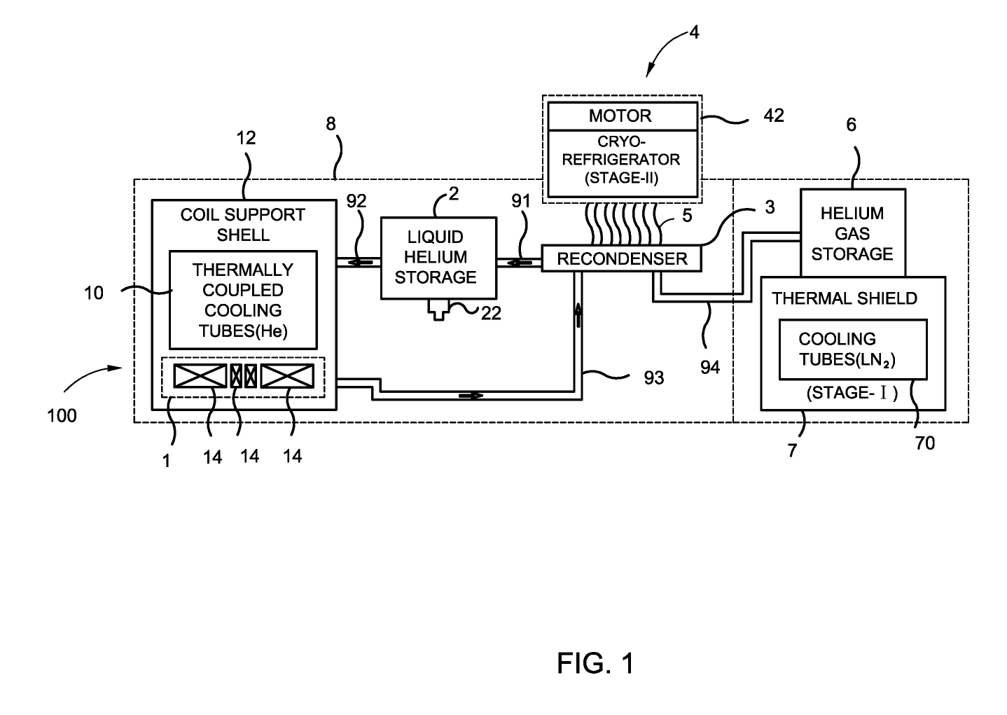

FIG. 1 illustrates a schematic block diagram of a superconducting magnet cooling system in accordance with an embodiment of the present invention. As shown in FIG. 1, a superconducting magnet cooling system 100 according to an embodiment of the present invention includes a superconducting magnet 1, a liquid cryogen vessel 2 for cooling the superconducting magnet 1, a heat exchanger device 3 in fluid communication with the liquid cryogen vessel 2, a cryorefrigerator 4 for heat exchange with heat exchanger device 3, and a flexible connection device 5 for thermally connecting the cryorefrigerator 4 with the heat exchanger device 3. The flexible connection device 5 has high thermal conductivity. By the flexible connection device 5 having high thermal conductivity, a thermal connection between the cryorefrigerator 4 and the heat exchanger device 3 is established, and at the same time, vibration isolation of the cryorefrigerator 4 from the heat exchange device 3 is also provided because of flexibility of the flexible connection device 5. The flexible connection device 5 can be designed to be highly flexible so that the vibration of the cryorefrigerator 4 cannot be transmitted to the superconducting magnet 1 when the cryorefrigerator 4 is in operation. The vibration isolation of the superconducting magnet 1 can be accomplished by the flexible connection device 5 thermally connecting the cryorefrigerator 4 to the recondenser 3.

In this embodiment, the liquid cryogen vessel 2 may be for example a liquid helium storage 2 which may be formed from one or more liquid helium reservoirs, and the heat exchanger device 3 may be for example a remote recondenser 3. The fluid communication between the recondenser 3 and the liquid helium storage 2 may be provided via one or more passageways 91.

With reference to FIG. 1, the superconducting magnet 1 comprises at least one coil support shell 12 and a plurality of superconducting magnet coils 14 supported and positioned by the at least one coil support shell 12. The coil support shell 12 is formed from a thermally conductive material (e.g. aluminum). A plurality of cooling tubes 10, which may be formed from any suitable metal (e.g., copper, stainless steel, aluminum, etc.), are thermally coupled to the at least one coil support shell 12 and are in fluid communication with the liquid helium storage 2. The liquid helium storage 2 has a cryogen inlet port 22 for providing the liquid cryogen, for example, the liquid He. The cryogen inlet port 22 provides a hermetically sealed configuration such that a closed-loop cooling system is provided. The liquid helium storage 2 contains the liquid He used in the closed-loop cooling system to cool the superconducting magnet coils 14. The fluid communication between the plurality of cooling tubes 10 and the liquid helium storage 2 may be provided via one or more fluid passageways 92. Thus, the liquid helium storage 2 provides the liquid He that flows through the cooling tubes 10 to cool the superconducting magnet coils 14.

Continuing to refer to FIG. 1, in an embodiment of the present invention, the superconducting magnet cooling system 100 is illustrated as a two stage cooling arrangement. However, the superconducting magnet cooling system 100 should not be limited hereinto, in fact, the superconducting magnet cooling system 100 of the present invention can be applied to any multi-stage cooling arrangement or a single stage cooling arrangement. The superconducting magnet cooling system 100 further comprises a gas cryogen vessel 6. In this embodiment, the gas cryogen vessel 6 may be for example a helium gas storage 6 which may be formed from one or more helium gas tanks. The plurality of cooling tubes 10 are also in fluid communication with a vapor return manifold 93, which is in fluid communication with the helium gas storage 6 through the recondenser 3. The helium gas storage 6 contains He gas received as He vapor from the cooling tubes 10 that removes the heat from the superconducting magnet coils 14 and forms part of the closed-loop cooling system. The fluid communication between the recondenser 3 and the helium gas storage 6 may be provided via one or more passageways 94.

The recondenser 3 draws He gas from the helium gas storage 6 that operates to form a free convection circulation loop to cool the superconducting magnet coils 14 and the coil support shell 12 to a cryogenic temperature, as well as fills the liquid helium storage 2 with liquid He via one or more passageways 91. The liquid He in the liquid helium storage 2 may be used to provide cooling of the superconducting magnet coils 14 during power interruptions or shut down of the cryorefrigerator 4, such as for service (e.g., for 10-12 hours).

As shown in FIG. 1, the superconducting magnet cooling system 100 further comprises a thermal shield 7, which may be in thermal contact with the helium gas storage 6. The thermal shield 7 is thermally coupled to a plurality of cooling tubes 70 (e.g., pre-cooling tubes), which are different than and not in fluid communication with the cooling tubes 10. For example, the cooling tubes 10 provide cooling using He and the cooling tubes 70 may provide cooling, or pre-cooling, using liquid nitrogen (LN₂).

In the superconducting magnet cooling system 100 of the present invention having two stage cooling arrangement, cooling with the thermal shield 7 may provide a first stage of cooling by direct contact with the first stage of the cryorefrigerator 4 at a temperature of about 40-50 K and may also provide pre-cooling for example, at a temperature between about 77 K and 80 K using the LN₂. The second stage of cooling is provided using the He cooling so as to provide an operation temperature of about 4.2 K.

The superconducting magnet cooling system 100 is located within a vacuum vessel 8. The cryorefrigerator 4 comprises a coldhead (not shown), a motor 42 for driving the coldhead to operate, and a coldhead sleeve 44. The coldhead of the cryorefrigerator 4 may be positioned within the coldhead sleeve 44 without affecting the vacuum within the vacuum vessel 8. The coldhead of the cryorefrigerator 4 is inserted (or received) and secured with the coldhead sleeve 44 using any suitable means, such as one or more flanges and bolts, or other suitable means. Moreover, the motor 42 of the cryorefrigerator 4 is provided outside the vacuum vessel 8.

Because the reconderser 3 and the cryorefrigerator 4 are thermally connected via the flexible connection device 5, all of the passageways 91, 92, 94 and the vapor return manifold 93 use a rigid high pressure piping so that the superconducting magnet cooling system 100 may be hermetically sealed with high pressure charged helium gas which is cooled directly by the cryorefrigerator 4 from an ambient temperature to a cryogenic temperature.

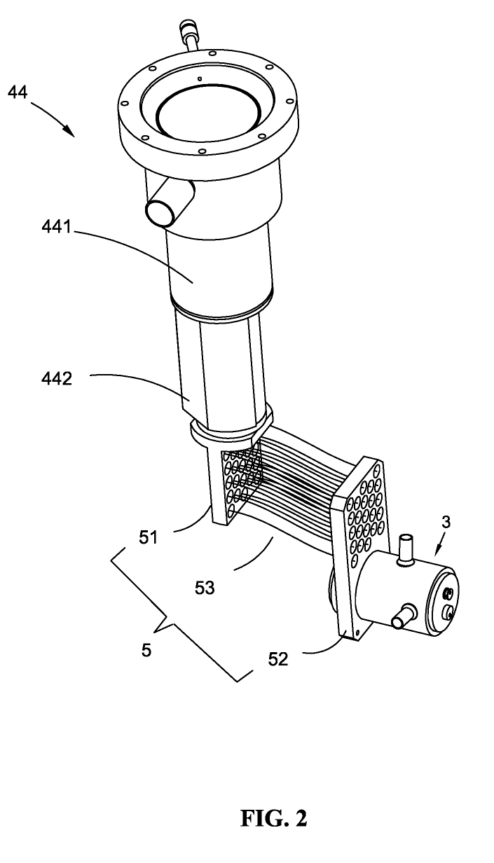

Referring to FIGS. 1 and 2, the cryorefrigerator 4 have two stages at different temperatures and the recondenser 3 is connected to a second stage of the cryorefrigerator 4 with the flexible connection device 5. In detail, the coldhead of the cryorefrigerator 4 has a first stage and a second stage, and correspondingly, the coldhead sleeve 44 also has a first stage 441 and a second stage 442 for respectively receiving the corresponding first and second stages of the coldhead. In this embodiment, the recondenser 3 is connected to the second stage 442 of the coldhead sleeve 44 of the cryorefrigerator 4 with the flexible connection device 5. The thermal shield 7 is connected to the first stage 441 of the coldhead sleeve 44 of the cryorefrigerator 4 also with a flexible connection similar to the flexible connection device 5, not shown.

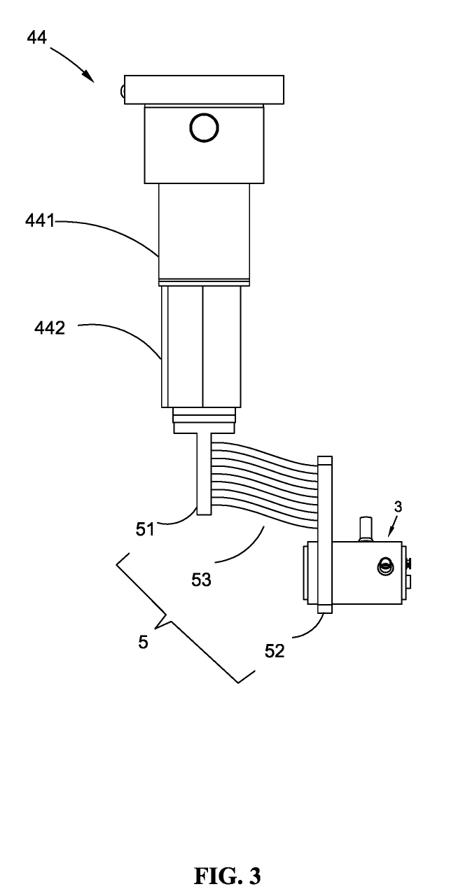

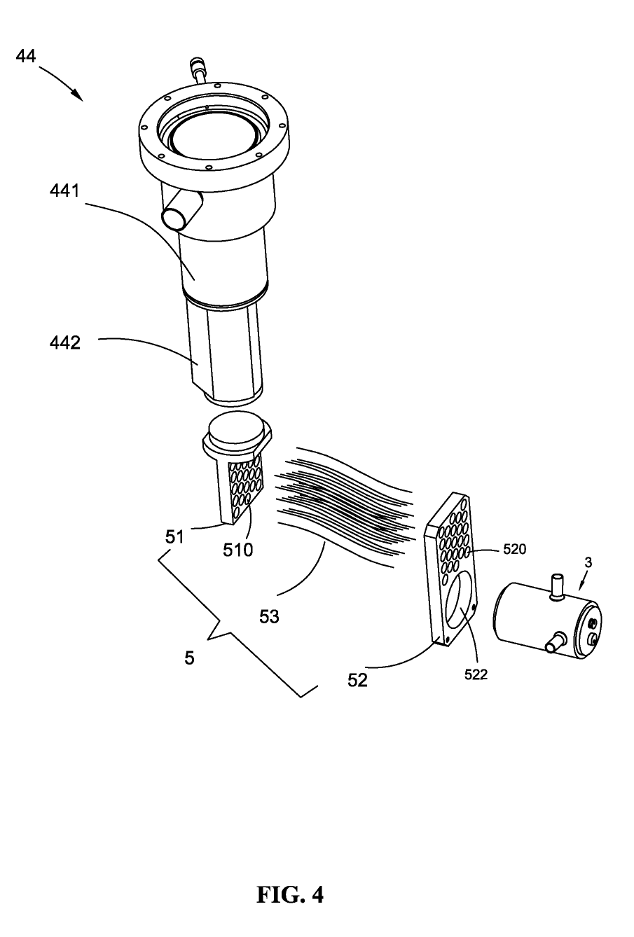

The flexible connection device 5 is made of braid structure for providing a flexible connection. In one embodiment, the flexible connection device 5 comprises copper braids. FIGS. 2-4 illustrate an embodiment of a connection between the cryorefrigerator 4 and the recondenser 3 of the present invention. As shown in FIGS. 2-4, in this embodiment, the flexible connection device 5 comprises a first connection member 51, a second connection member 52 and a plurality of wires 53 connected between the first connection member 51 and the second connection member 52. In this embodiment, the first connection member 51, the second connection member 52 and the plurality of wires 53 are all made from copper. However, the material that the first connection member 51, the second connection member 52 and the plurality of wires 53 use should not be limited to copper, other materials having high thermal conductivity should be also applicable. The first connection member 51 is disposed on the second stage 442 of the coldhead sleeve 44. As shown in FIG. 4, for example, in an embodiment, the first connection member 51 is welded onto a free end of the second stage 442 of the coldhead sleeve 44. The first connection member 51 defines a plurality of holes 510 therein. The second connection member 52 is disposed on the recondenser 3. As shown in FIG. 4, for example, in an embodiment, the second connection member 52 defines a plurality of holes 520 and an aperture 522 therein. The recondenser 3 is inserted into and then is welded onto the aperture 522 of the second connection member 52. The plurality of wires 53 may be respectively welded onto the plurality of holes 510, 520 of the first and the second connection members 51, 52. The second stage 442 of the coldhead sleeve 44 is thus thermally connected to the recondenser 3 by the flexible connection device 5. The flexible connection device 5 as shown in FIGS. 2-4 is only as an exemplary example of the present invention. However, the flexible connection device 5 of the present invention should not be only limited to the structure shown in FIGS. 2-4 and may also adopt other structure. Any one flexible connection for realizing a thermal connection between the recondenser 3 and the cryorefrigerator 4 will be included in the protective scope of the flexible connection device 5 of the present invention.

In the superconducting magnet cooling system 100 of the present invention, by adopting the flexible connection device 5 having high thermal conductivity, not only a thermal connection between the cryorefrigerator 4 and the recondenser 3 is established, but also vibration isolation of the cryorefrigerator 4 from the recondenser 3 is also provided because of flexibility of the flexible connection device 5. Therefore, the vibration of the cryorefrigerator 4 cannot be transmitted to the superconducting magnet 1. The vibration isolation of the superconducting magnet 1 can be accomplished by the flexible connection device 5 thermally connecting the cryorefrigerator 4 to the recondenser 3.

Furthermore, because the reconderser 3 and the cryorefrigerator 4 are thermally connected via the flexible connection device 5, this design of the superconducting magnet cooling system 100 enables the use of high pressure piping between the liquid cryogen vessel 2 and superconducting magnet 1 that is inherently rigid and is able to use a hermetically sealed high pressure charged helium gas which is cooled directly by the cryorefrigerator 4 from the ambient temperature to the cryogenic temperature.

While the disclosure has been illustrated and described in typical embodiments, it is not intended to be limited to the details shown, since various modifications and substitutions can be made without departing in any way from the spirit of the present disclosure. As such, further modifications and equivalents of the disclosure herein disclosed may occur to persons skilled in the art using no more than routine experimentation, and all such modifications and equivalents are believed to be within the spirit and scope of the disclosure as defined by the following claims.

We claim:

1. A superconducting magnet cooling system, comprising:
a superconducting magnet;
a liquid cryogen vessel for cooling the superconducting magnet;
a heat exchanger device in fluid communication with the liquid cryogen vessel;
a cryorefrigerator for heat exchange with the heat exchanger device; and
a flexible connection device having high thermal conductivity and thermally connecting the cryorefrigerator and the heat exchanger device to provide vibration isolation of the cryorefrigerator from the heat exchange device.

2. The superconducting magnet cooling system of claim 1, wherein the flexible connection device is made of braid structure.

3. The superconducting magnet cooling system of claim 2, wherein the flexible connection device comprises copper braids.

4. The superconducting magnet cooling system of claim 1, wherein the cryorefrigerator have two stages at different temperatures and the heat exchanger device is connected to a second stage of the cryorefrigerator with the flexible connection device.

5. The superconducting magnet cooling system of claim 4, wherein the cryorefrigerator comprises a coldhead having first and second stages, a motor for driving the coldhead to operate, and a coldhead sleeve within which the coldhead is positioned and having first and second stages for receiving the corresponding first and second stages of the coldhead, the heat exchanger device being connected to the second stage of the coldhead sleeve of the cryorefrigerator with the flexible connection device.

6. The superconducting magnet cooling system of claim 5, wherein the flexible connection device comprises a first connection member disposed on the second stage of the coldhead sleeve, a second connection member disposed on the heat exchange device and a plurality of wires connected between the first connection member and the second connection member.

7. The superconducting magnet cooling system of claim 6, wherein the first connection member, the second connection member and the plurality of wires are made from copper.

8. The superconducting magnet cooling system of claim 1, wherein the heat exchange device is rigidly connected to the liquid cryogen vessel.

9. The superconducting magnet cooling system of claim 8, wherein the heat exchange device is fluidly communicated to the liquid cryogen vessel with a rigid high pressure piping.

10. The superconducting magnet cooling system of claim 5, further comprising a gas cryogen vessel in fluid communication with the heat exchanger device.

11. The superconducting magnet cooling system of claim 10, wherein the gas cryogen vessel is fluid communicated to the heat exchanger device with a rigid high pressure piping.

12. The superconducting magnet cooling system of claim 10, wherein the liquid cryogen vessel is a liquid helium storage, and the gas cryogen vessel is a helium gas storage.

13. The superconducting magnet cooling system of claim 10, further comprising a vacuum vessel, wherein the superconducting magnet cooling system is located within the vacuum vessel.

14. The superconducting magnet cooling system of claim 10, further comprising a thermal shield in thermal contact with the gas cryogen vessel.

15. The superconducting magnet cooling system of claim 14, wherein the thermal shield is connected to the first stage of the coldhead sleeve of the cryorefrigerator with a flexible connection having high thermal conductivity.

16. The superconducting magnet cooling system of claim 1, wherein the heat exchanger device is a remote recondenser.

17. The superconducting magnet cooling system of claim 1, wherein the superconducting magnet comprises at least one coil support shell and a plurality of superconducting magnet coils supported by the at least one coil support shell, the superconducting magnet cooling system comprising a plurality of cooling tubes thermally coupled to the at least one coil support shell and fluidly coupling with the liquid cryogen vessel.
